(19) United States
(12) Patent Application Publication
(10) Pub. No.: US 2010/0282948 A1
(43) Pub. Date: Nov. 11, 2010

(54) OPTICAL SEMICONDUCTOR DEVICE

(75) Inventors: Tsutomu MIYAJIMA, Osaka (JP); Hisatada YASUKAWA, Kyoto (JP)

Correspondence Address: Stephen A. Becker;McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/838,937

(22) Filed: Jul. 19, 2010

Related U.S. Application Data
(63) Continuation of application No. PCT/JP2009/005313, filed on Oct. 13, 2009.

(30) Foreign Application Priority Data
Oct. 22, 2008 (JP) 2008-271798

(51) Int. Cl. H01L 31/10; H01L 31/0352

(52) U.S. Cl. 250/214 A; 257/463; 257/E31.037; 257/E31.053

(57) ABSTRACT

An optical semiconductor device comprises a first semiconductor region of a first conductivity type and a second semiconductor region of a second conductivity type formed on the first semiconductor region. The device further comprises a third semiconductor region of the first conductivity type formed in a semiconductor layer, which is separated from the first and second semiconductor regions by an element separation region, and a fourth semiconductor region of the first conductivity type formed between a semiconductor substrate and third semiconductor region. The device further comprises a fifth semiconductor region of the first conductivity type formed across the semiconductor substrate and the first semiconductor region. An upper portion of the fifth semiconductor region penetrates into a specific depth of the first semiconductor region. Amplification of a current signal occurs when a reverse voltage is applied between the second semiconductor region and a surface portion of the third semiconductor region.

### CROSS-REFERENCE TO RELATED APPLICATION

This is a continuation of International Application No. PCT/JP2009/005313 filed on Oct. 13, 2009, which claims priority to Japanese Patent Application No. 2008-271798 filed on Oct. 22, 2008. The disclosures of these applications including specifications, drawings and claims are incorporated herein by reference in their entireties.

### BACKGROUND OF THE INVENTION

1. Field of the Invention

The present invention relates to an optical semiconductor device and particularly to an optical semiconductor device in which a light-receiving element and a logical element are formed on a same substrate.

2. Description of the Related Art

An opto-electronic integrated circuit (OEIC) device is a type of an optical semiconductor device, in which a light-receiving element such as a photodiode converting an optical signal to an electric signal, an active element such as a transistor element constituting a peripheral circuit, and a passive element such as a resistor element and a capacitor element are formed on a same substrate. Such an OEIC device is used as optical pickup devices for optical discs which are capable of converting an optical signal to an electric signal and various optical sensors.

OEIC devices used as an optical pickup device are desired to be improved in light-receiving sensitivity and operation speed as optical discs have higher densities and recording speeds. Moreover, in addition to those for CDs (compact discs) utilizing infrared light and those for DVDs (digital versatile discs) utilizing red light, recent optical pickup devices for BDs (blue digital versatile discs) utilize blue light. Therefore, there is a demand for a single optical pickup device capable of detecting optical signals from light sources of three different wavelengths. Particularly, BDs require high speed response because of their high data density. Then, in addition to conventional OEIC devices having light-receiving sensitivity and high speed response to infrared and red light, an OEIC device additionally having light-receiving sensitivity and high speed response to blue light is demanded.

A light absorption amount of a semiconductor for light of each of the three different wavelengths is explained hereafter. The light absorption amount of a semiconductor varies depending on the wavelength of incident light. The light absorption amount of a semiconductor at a depth t below an entrance surface for incident light having a particular wavelength and an absorption coefficient α is expressed by 1−e^{αt} (e is the base of natural logarithm). For example, a depth from an entrance surface at which about 90% of the incident light has been absorbed by a silicon semiconductor is approximately 24 μm for infrared light having a wavelength of 780 nm, approximately 7.7 μm for red light having a wavelength of 650 nm, and approximately 0.6 μm for blue light having a wavelength of 405 nm. On light-receiving properties, light-receiving sensitivity and response speed can be improved by efficiently generating electron-hole pairs with respect to the number of photons depending on the wavelength of light and extracting the electrons or holes as carriers contributing to the current in an electrically efficient manner.

A current-amplifying photodiode using avalanche multiplication is a type of an optical semiconductor device possibly allowing for high light-receiving sensitivity. However, a general current-amplifying photodiode requires extremely high voltage operation. Therefore, a high voltage power source and a bias control circuit for controlling the high voltage to maintain a constant amplifying rate are required, increasing power consumption and production cost. Then, there is a demand for an optical semiconductor device having high light-receiving sensitivity in low voltage operation that requires no high voltage power source and operates with a simple drive circuit without voltage control.

Visible light communication systems using fluorescent lamps or visible light LEDs (light emitting diodes) have increasing values in use as sensor devices in accordance with recent large volume data transfer between various terminals in a space transmission field. Particularly, as a result of accelerated development of LED lighting for saving lighting apparatus power consumption, high speed data transfer using lighting LEDs are now realizable among visible light communication systems using room lighting. Therefore, visible light communication systems using room lighting are expected to dominate the future space transmission field as a means for home space transmission network communication.

Light-receiving elements of visible light communication devices are required to assure a space transmission distance and to be able to detect high frequency optical signals. Characteristics of irradiation light serving as a signal source include wide-area irradiation light and the use of white light. As for the light-receiving properties in regard to wide-area irradiation light, the quantity of light per unit area of wide-area irradiation light varies depending on a distance. Therefore, the quantity of incident light introduced in the light-receiving region varies depending on a transmission distance. Furthermore, white light includes light of all wavelengths in the visible light range. Therefore, the light-receiving element needs to have light-receiving sensitivity to light of the entire range of visible light wavelengths. Furthermore, the light-receiving element detecting signals must thoroughly detect optical signals within the space transmission distance, requiring a high level of performance in light-receiving sensitivity. Signal detection performance within several meters is required for home lighting and signal detection performance within several tens of meters is required for business lighting.

Devices using the light-receiving elements as described above tend to have increased power consumption because of their multifunctional signal control circuits from the viewpoint of demand for high functionality although low power consumption is desired from an ecological point of view. As seen from the above, the light-receiving element must have high light-receiving sensitivity and high speed response in low voltage operation regardless of application fields. Some structures of amplifying photodiode elements as conventional optical semiconductor devices are described below.

### Conventional Example 1

FIG. 12 is a cross-sectional view showing a structure of an optical semiconductor device according to Conventional Example 1 (for example, see Japanese Laid-Open Patent Application Publication No. 2000-252507). This optical semiconductor device has a semiconductor substrate 81 consisting of a low impurity concentration P type silicon (Si) having a specific resistance of 150 Ωcm, on which an N+ type semiconductor layer 82 consisting of a semiconductor containing a high concentration of impurity is formed. A P− type semiconductor layer 83 having an impurity concentration lower than that of the N+ type semiconductor layer 82 is formed on the N+ type semiconductor layer 82. A P+ semiconductor layer 84 having an impurity concentration higher than that of the P− type semiconductor layer 83 is formed on the P− type semiconductor layer 83. A P++ type semiconductor layer 85 having an impurity concentration further higher than that of the P+ type semiconductor layer 84 is formed on a peripheral portion of the P+ type semiconductor layer 84. The P++ type semiconductor layer 85 serves as an anode contact layer of a photodiode.

Furthermore, an N++ type semiconductor layer 86 having an impurity concentration further higher than that of the N+ type semiconductor layer 82 is formed on an edge portion of the N+ type semiconductor layer 82. The N++ type semiconductor layer 86 serves as a cathode contact layer of the photodiode. An anode electrode 87 and a cathode electrode 88 are formed on the contact layers 85 and 86, respectively. The P++ type semiconductor layer 85 and P+ type semiconductor layer 84, and N++ type semiconductor layer 86 are separated by element separation insulating layers 91. The light-receiving element having this structure has a light-receiving region indicated by a reference number 89.

Operation of the light-receiving portion of the optical semiconductor device of Conventional Example 1 having the above structure is described hereafter with reference to FIGS. 12, 13A and 13B. FIG. 13A is a chart showing an impurity concentration along a line a-b in the optical semiconductor device of Conventional Example 1 shown in FIG. 12. FIG. 13B is a chart showing an energy band along the line a-b in the optical semiconductor device of Conventional Example 1.

First, light entering the light-receiving region 89 passes through a surface protection film layer 100 and irradiates a surface of the P+ type semiconductor layer 84. Photons, which are an entity of irradiation light, are absorbed in the semiconductor at an exponential rate according to the optical absorption coefficient, which is a physical constant. Therefore, they attenuate and disappear at some point as they proceed into the semiconductor layers. Absorbed photons yield electron-hole pairs, generating photocurrent. As shown in FIG. 13A, the P+ type semiconductor layer 84 is a high concentration region near the surface. The photons absorbed by the P+ type semiconductor layer 84 yield electron-hole pairs, which are primarily subject to diffusion because of a nearly flat energy band in a depth direction as shown in FIG. 13B.

Then, electron-hole pairs generated in the P− type semiconductor layer 83, which is a low concentration region having a concentration gradient shown in FIG. 13A, move in a region having a potential gradient (depletion layer region) shown in FIG. 13B. Therefore, they are primarily subject to drifting under electric field in the P− type semiconductor layer 83. The response speed is highest in this region. With a high voltage applied between the cathode electrode 88 and the anode electrode 87, the potential gradient in the P− type semiconductor layer 83 is steepened. Such application of a high voltage leads to multiplication of the generated carriers (avalanche multiplication), realizing amplification of the photocurrent.

The P− type semiconductor layer 83 of Conventional Example 1 has a large thickness for realizing high light-receiving sensitivity and high response speed for light of a wide range of wavelengths. In this way, absorbance for light of longer wavelengths is assured and the depletion layer is created in the P− type semiconductor layer 83 so as to reduce a PN junction capacitance of the photodiode, preventing device performance deterioration for the incident light signal frequency.

In this structure, as shown in FIGS. 13A and 13B, taking light absorption rate into consideration, the depletion layer region having a sufficient width and area should be created between the P+ type semiconductor layer 84 and N+ type semiconductor layer 82. For example, the P− type semiconductor layer 83 extends to a depth of 7.7 μm or larger below the surface of the optical semiconductor device for the abovementioned light having a wavelength of 650 nm. In order to cause avalanche multiplication in this depletion layer, the photodiode should be in an approximately 60 V or larger reverse bias state. Therefore, against the demand for low power consumption, large power is required for operation of an optical semiconductor device including a light-receiving element and logic circuits. A following structure having improvements made on the structure in Conventional Example 1 has been proposed for realizing low voltage operation and avalanche multiplication (for example, see Japanese Laid-Open Patent Application Publication No. H11-45988).

### Conventional Example 2

FIG. 14 is a cross-sectional view showing a structure of an optical semiconductor device of Conventional Example 2 wherein a P+ type semiconductor layer 90 having an impurity concentration higher than that of the P− type semiconductor layer 83 and lower than that of the N+ type semiconductor layer 82 is selectively added in the P− type semiconductor layer 83 of the optical semiconductor device shown in FIG. 12. Furthermore, the P− type semiconductor substrate 81 consists of a low impurity concentration P type silicon (Si) having a specific resistance of approximately 150 Ωcm. Operation of the light-receiving portion of the optical semiconductor device of Conventional Example 2 is described hereafter with reference to FIGS. 15A and 15B.

FIG. 15A is a chart showing an impurity concentration along a line a-b in the optical semiconductor device of Conventional Example 2 shown in FIG. 14. FIG. 15B is a chart showing an energy band along the line a-b in the optical semiconductor device of Conventional Example 2. This structure characteristically has a high concentration layer, namely the P+ type semiconductor layer 90, inside the P− type semiconductor layer 83.

Therefore, as seen from the energy band diagram in FIG. 15B, the P+ type semiconductor layer 90 formed in the P− type semiconductor layer 83 is close to the N+ type semiconductor layer 82 and even a low voltage causes a steep potential gradient between the P+ type semiconductor layer 90 and N+ type semiconductor layer 82. Multiplication of generated carriers (avalanche multiplication) occurs in this steep region with application of a low voltage, realizing amplification of the photocurrent. However, in Conventional Example 2, electrons and holes generated between the surface and the top surface of the P+ type semiconductor layer 90 upon light absorption do not contribute to the avalanche multiplication. Therefore, the structure does not exhibit high light-receiving sensitivity to light of short wavelengths, which will generate most electron-hole pairs at a shallow portion of the P− type semiconductor layer 83.

### SUMMARY OF THE INVENTION

As described above, light-receiving elements must have the capability of high light-receiving sensitivity, high speed response and low power consumption. As for high light-receiving sensitivity, short wavelength light such as blue light has larger energy per photon and holds a smaller number of photons for the same optical output power, compared to infrared and red light. Therefore, a smaller number of carriers are generated from photoelectric conversion, leading to reduced light-receiving sensitivity. Assuming that quantum efficiency is 100% (one electron-hole pair is generated from one photon), the light-receiving sensitivity to light having the aforementioned wavelengths is 0.63 A/W for infrared light, 0.52 A/W for red light and 0.33 A/W for blue light. For this reason, a structure ensuring high light-receiving sensitivity to short wavelength light is desired.

However, in the conventional optical semiconductor devices described above, the structure realizing high light-receiving sensitivity and high speed response to light of a wide range of wavelengths requires application of a high voltage to amplify photocurrent and increases power consumption as in Conventional Example 1. On the other hand, the structure realizing current amplification in low voltage operation restrains high light-receiving sensitivity to short wavelength light as in Conventional Example 2. Furthermore, it is necessary for realizing high speed response to reduce parasitic capacitance and parasitic resistance, which otherwise may deteriorate the performance for the frequency of optical signal entering from the above-described light-receiving region 89. However, in the optical semiconductor devices of the Conventional Examples, parasitic capacitance and parasitic resistance are not sufficiently reduced although consideration is made in regard to the cross-sectional structure.

In view of the above problems, the purpose of the present invention is to improve a light-receiving element of an optical semiconductor device in operation properties (light-receiving sensitivity and high speed response) for light of a wide range of wavelengths from short wavelength light to visible light and to realize low power consumption in an optical semiconductor device. Furthermore, the present invention provides a light-receiving element having a structure easily mountable in an IC with elements such as NPN transistors and vertical PNP transistors.

In order to achieve the above purpose, an optical semiconductor device according to the present invention includes a light-receiving element performing current amplification in a light-receiving operation portion converting an incident light signal to a current signal. The light-receiving operation portion comprises a semiconductor layer of a first conductivity type formed on a semiconductor substrate of the first conductivity type and having an impurity concentration equal to or lower than that the semiconductor substrate, a first semiconductor region of the first conductivity type formed by delimiting a specific region of the semiconductor layer with an element separation region, and a second semiconductor region of a second conductivity type formed on the semiconductor layer and having an impurity concentration higher than that the first semiconductor region.

Furthermore, the light-receiving operation portion comprises a third semiconductor region of the first conductivity type formed in the semiconductor layer that is insulated and separated from the first and the second semiconductor regions and having an impurity concentration higher than that the first semiconductor region, and a fourth semiconductor region of the first conductivity type formed between the semiconductor substrate and the third semiconductor region and having an impurity concentration higher than that the semiconductor substrate. The light-receiving operation portion further comprises a fifth semiconductor region of the first conductivity type formed across the semiconductor substrate and the semiconductor layer and having an impurity concentration higher than that the semiconductor substrate. In the light-receiving operation portion, amplification of the current signal, the amplification being based on avalanche multiplication, occurs when a reverse voltage is applied between the second semiconductor region and a surface portion of the third semiconductor region.

In the optical semiconductor device according to the present invention, the light-receiving operation portion generating photocurrent and amplifying the current is formed on a semiconductor substrate, converting an optical signal received through incident light to photocurrent and amplifying the current. Therefore, a signal can be detected even if incident light has low power. Particularly, avalanche multiplication occurs between the second and fifth semiconductor regions with an application of a low voltage, whereby photocurrent holding optical signal information can be amplified. Consequently, the light-receiving sensitivity can be improved without increasing a thickness of the second semiconductor region having the second conductivity type, and high-speed response and high-frequency performance can also be improved. Furthermore, light-receiving sensitivity can be improved not only to infrared and red light but also to blue light.

It is preferable in the above structure that the fourth and fifth semiconductor regions are partly in contact with each other at more than one place. In this way, carriers generated due to the second and fifth semiconductor regions (carriers generated in avalanche multiplication) can move between the fifth and fourth semiconductor regions without passing through the aforementioned semiconductor layer. Consequently, contact resistance can be reduced and deterioration of frequency performance can be prevented.

It is further preferable in the above structure that the fifth semiconductor region has a spiral or radial pattern or a pattern including such a pattern in a planar layout. In this way, a depletion layer is sufficiently created in the semiconductor layer, reducing parasitic capacitance. Therefore, the light-receiving sensitivity can be improved by means of avalanche multiplication and the frequency performance can be improved as a result of reduced parasitic capacitance other than a portion that avalanche multiplication is occurred. Moreover, since incident light has a nearly circular cross-section, the incident light can be irradiated at a specific point on the planar layout in a case that the incident light is irradiated in a positionally stable manner. Consequently, stabilized performance can be realized even if an optical diameter of incident light is changed.

It is further preferable in the above structure that the fifth semiconductor region has a pattern in a planar layout such that an area ratio of the fifth semiconductor region to an irradiation area of incident light is always constant in the irradiation area. The number of photons contained in incident light varies depending on a power of incident light. The light-receiving element receives the same number of photons for the same power even if the optical diameter of incident light is changed. With the above structure, a given level of light-receiving sensitivity can be obtained with no influence from change in the optical diameter of incident light. In this manner, when the area of the fifth semiconductor region is minimized for realizing high frequency performance, stable high light-receiving sensitivity can be obtained. Then, a light-receiving element having high speed response and high frequency performance and a given level of high light-receiving sensitivity can be formed. When circuit elements such as transistors are integrated on the same substrate, circuit elements can be formed without any restriction based on the requirement of light-receiving element properties.

With an optical semiconductor device according to the present invention, the light-receiving element consisting of the first semiconductor region and the semiconductor layer multiplies generated carriers in the light-receiving operation portion, whereby sufficient light-receiving sensitivity can be obtained for short wavelength light such as blue light. Furthermore, a low avalanche voltage can be used for causing current amplification, realizing a lower power consumption optical semiconductor device, which has various applications. Furthermore, reduced parasitic capacitance and parasitic resistance leads to improved frequency performance, realizing high speed response along with high light-receiving sensitivity.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are cross-sectional and plane views showing a light-receiving element of an optical semiconductor device in a first embodiment relating to the present invention.

FIG. 2 is an illustration showing an electric field in a light-receiving element of an optical semiconductor device in a first embodiment relating to the present invention.

FIGS. 3A and 3B are charts showing a potential profile in a light-receiving element of an optical semiconductor device in a first embodiment relating to the present invention.

FIG. 4 is an illustration showing an electric field in a light-receiving element of an optical semiconductor device in a first embodiment relating to the present invention.

FIG. 5 is an illustration showing an electric field in a light-receiving element of an optical semiconductor device in a first embodiment relating to the present invention.

FIGS. 6A and 6B are illustrations showing a manufacturing process of a light-receiving element of an optical semiconductor device in a first embodiment relating to the present invention.

FIGS. 7A and 7B are illustrations showing a manufacturing process of a light-receiving element of an optical semiconductor device in a first embodiment relating to the present invention.

FIG. 8 is a plane view showing another light-receiving element of an optical semiconductor device in a first embodiment relating to the present invention.

FIG. 9 is a plane view showing another light-receiving element of an optical semiconductor device in a first embodiment relating to the present invention.

FIG. 10 is a plane view showing a further other light-receiving element of an optical semiconductor device in a first embodiment relating to the present invention.

FIG. 11 is a cross-sectional view showing an optical semiconductor device in a second embodiment relating to the present invention.

FIG. 12 is a cross-sectional view showing a conventional light-receiving element.

FIGS. 13A and 13B are charts showing a potential profile in the conventional light-receiving element.

FIG. 14 is a cross-sectional view showing another conventional light-receiving element.

FIGS. 15A and 15B are charts showing a potential profile in the other conventional light-receiving element.

### DETAILED DESCRIPTION OF PREFERRED EMBODIMENTS

An embodiment of the present invention is described hereafter with reference to the drawings.

### First Embodiment

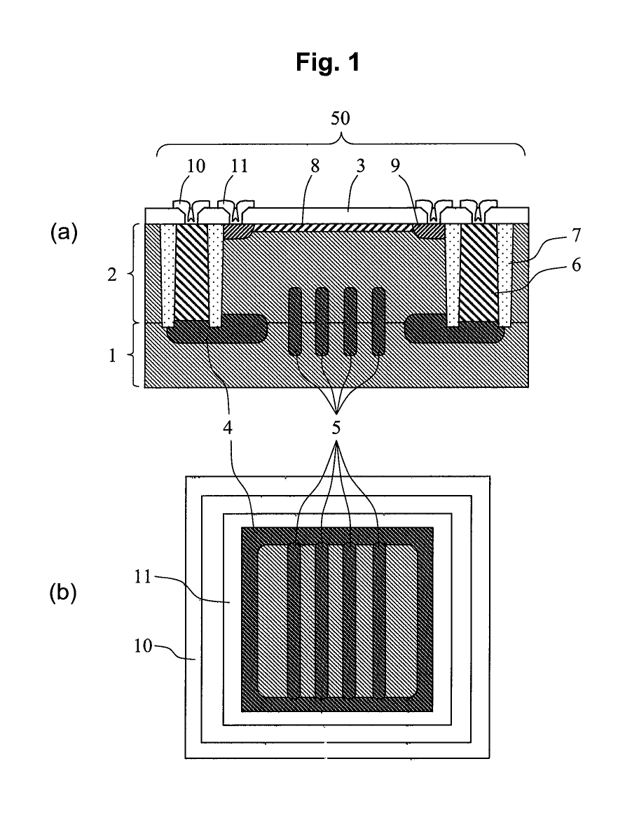

FIG. 1A is a cross-sectional view showing a light-receiving element of an optical semiconductor device in a first embodiment relating to the present invention. FIG. 1B is an illustration showing an exemplary planar layout of the light-receiving element. As described in detail hereafter, a light-receiving element portion 50 of this embodiment is characterized by a structure amplifying current using avalanche multiplication near a surface within a light-receiving region where incident light is converted to current signals.

As shown in the cross-sectional view of FIG. 1A, the device includes a P− type semiconductor substrate 1 consisting of a P type silicon (Si) having a low impurity concentration and a specific resistance of, for example, approximately 100 to 200 Ωcm, on which a P− type semiconductor layer 2 having a thickness of 2 μm and an impurity concentration equal to or lower than that of the P− type semiconductor substrate 1, for example, 1×10¹⁴ cm⁻³ is formed by using epitaxial growth. The light-receiving element portion 50 is surrounded and separated by an element separation insulating layer 7 (element separation region) in a form of a trench filled with silicon oxide (SiO₂). The element separation insulating layer 7 below a region between an anode electrode 10 and a cathode electrode 11 is formed deeper than the P− type semiconductor layer 2. A protective insulating film 3 consisting of, for example, silicon oxide is formed as a passivation film on the P− type semiconductor layer 2 except for a region where the electrodes are formed.

An N+ type semiconductor region 8 (a second semiconductor region), for example, having a peak impurity concentration at a depth of 0.1 μm below a top surface of the P− type semiconductor layer 2, a thickness of 0.2 μm, and a high impurity concentration of approximately 1×10¹⁸ cm⁻³ is selectively formed in a surface portion of the P− type semiconductor layer 2 that is delimited by the element separation insulating layer 7 (a first semiconductor region). The N+ type semiconductor region 8 can be provided on the P− type semiconductor layer 2 as a semiconductor layer separately from the P− type semiconductor layer 2. An N+ type semiconductor region 9 serving as a cathode contact layer is formed at an edge portion of the N+ type semiconductor region 8 by selectively implanting an N type impurity at a high concentration by ion implantation and annealing the N type impurity.

Furthermore, the cathode electrode 11 is formed on the N+ type semiconductor region 9. A P+ type semiconductor region 5 (a fifth semiconductor region) is formed by selectively implanting a P type impurity by ion implantation from the top surface of the P− type semiconductor substrate 1, annealing the P type impurity, and then epitaxially growing the P− type semiconductor layer 2. This diffusion layer extends approximately 1 μm upward from an interface between the P− type semiconductor substrate 1 and P− type semiconductor layer 2 and has an impurity concentration of 1×10¹⁸ cm⁻³. The selectively formed P+ type semiconductor region 5 has a slit pattern as shown in FIG. 1B in a planar layout.

A P+ type semiconductor region 6 (a third semiconductor region) having a peak impurity concentration at a depth of, for example, 1 μm below the top surface of the P− type semiconductor layer 2, a thickness of 2 μm, and an impurity concentration of approximately 1×10¹⁸ cm⁻³ is selectively formed around the element separation insulating layer 7 separating the N+ type semiconductor region 9 by ion implantation. A P+ type semiconductor region 4 (a fourth semiconductor region) is selectively formed below the P+ type semiconductor region 6 in the same method as the P+ type semiconductor region 5. This diffusion layer extends, for example, approximately 0.3 μm upward from the interface between the P− type semiconductor substrate 1 and P− type semiconductor layer 2 and has an impurity concentration of 1×10¹⁸ cm⁻³. Furthermore, the anode electrode 10 is formed on the P+ type semiconductor region 6.

Both the cathode electrode 11 and the anode electrode 10 have a ring shape in a planar pattern. The P+ type semiconductor region 6 is provided so as to surround the N+ type semiconductor region 9 and P− type semiconductor layer 2, with the element separation insulating layer 7 interposed therebetween. In other words, the element separation insulating layer 7 is formed on an inner side and outer side of the P+ type semiconductor region 6 in a planar pattern. By this arrangement, electric field concentration due to an applied voltage between the cathode electrode 11 and the anode electrode 10 during operation is alleviated. With the diffusion layers and separation layer being formed, the light-receiving element portion 50 is constructed. Unlike conventional optical semiconductor devices, the P+ type semiconductor region 5 is positioned deep below the surface of the P− type semiconductor layer 2 and selectively formed as shown in FIGS. 1A and 1B.

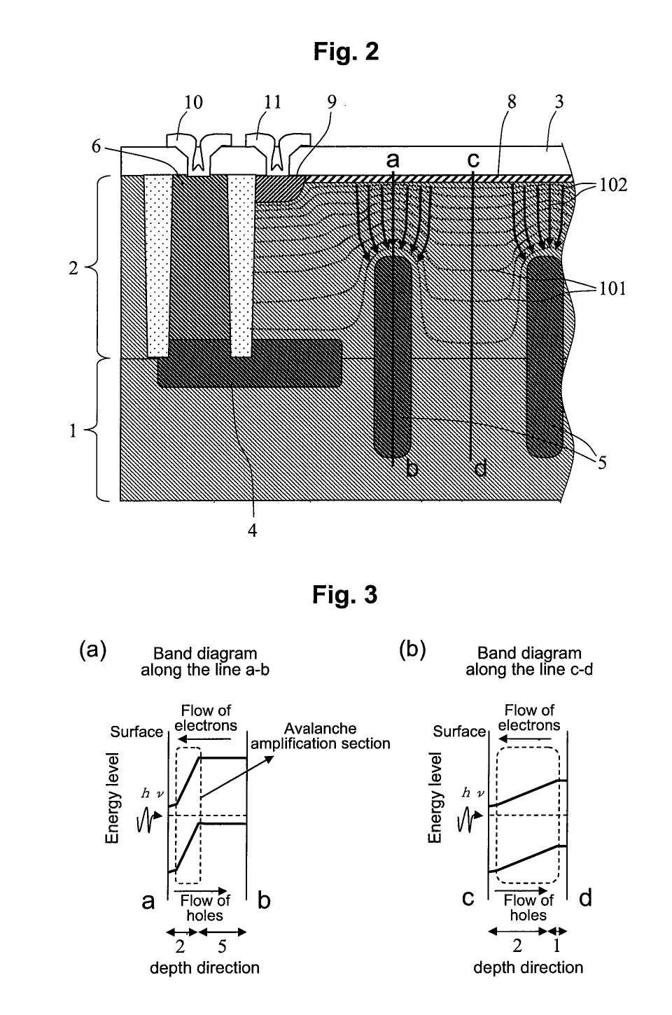

A current amplification process in the light-receiving element of this embodiment is described hereafter. FIG. 2 is a schematic illustration showing equipotential lines 101 and electric force lines 102 during light reception and current amplification of the light-receiving element in this embodiment. FIGS. 3A and 3B are charts showing a potential profile (energy band diagram) in cross-sections along a line a-b and line c-d in FIG. 2, respectively. In FIGS. 3A and 3B, a depth just below the N+ type semiconductor region 8 on the surface of the light-receiving element is plotted as abscissa and a potential for electrons is plotted as ordinate. Here, a reverse bias voltage is applied between the anode and cathode. Some regions shown in FIGS. 1A and 1B are omitted in FIG. 2 because they are irrelevant to the explanation.

First, electron-hole pairs are generated in the P− type semiconductor layer 2 upon irradiation of light on the light-receiving element portion 50. A slightly less than 1 μm region of the P− type semiconductor layer 2 between the P+ type semiconductor region 5 and N+ type semiconductor region 8 has a steep potential gradient as shown in the potential profile along the line a-b of FIGS. 2 and 3A. Therefore, even if a low voltage is applied between the anode electrode 10 and the cathode electrode 11, the generated electrons/holes are multiplied (avalanche multiplication), whereby photoelectric current can be amplified (avalanche amplification). Consequently, a voltage applied between an upper end portion that is near the N+ type semiconductor region 8 and a lower end portion that is near the P+ type semiconductor region 5 in the P− type semiconductor layer 2 where avalanche breakdown occurs is a low voltage, whereby current amplification occurs in this region with a low voltage. On the other hand, the region along the line c-d of the P− type semiconductor layer 2 interposed between the P+ type semiconductor regions 5 selectively formed in a planar layout has a sufficient distance from a PN junction of the N+ type semiconductor region 8 to a lower end of the P− type semiconductor layer 2. Therefore, as shown in FIGS. 2 and 3B, the region c-d of the P− type semiconductor layer 2 has a relatively gentle potential gradient in the depth direction and a depletion layer extends in the vertical direction.

Hence, even if a voltage is applied between the upper and lower ends of the region of the P− type semiconductor layer 2, namely in the region along the line a-b, where amplification due to avalanche breakdown occurs, no amplification occurs in the region along the line c-d. Instead, a depletion layer substantially extending in the region along the line c-d of the P− type semiconductor layer 2 interposed between the P+ type semiconductor regions 5 contributes to reduction in parasitic capacitance present within the light-receiving element. Here, the response speed of the light-receiving element is represented by a frequency performance (cut-off frequency) fc, which can be expressed fc=1/2πCR (C: capacitance, R: resistance). This means that reduced capacitance leads to improved frequency performance. Consequently, the selectively formed P+ type semiconductor region 5 in this structure contributes to reduced parasitic capacitance C, which leads to improved frequency performance and higher response speeds.

Because of the steep potential gradient created in the near-surface region of the P− type semiconductor layer 2 (the region along the line a-b), avalanche amplification occurs with short wavelength light that is primarily absorbed near the surface. Conventional light reception occurs in the region of the P− type semiconductor layer 2 interposed between the selectively formed P+ type semiconductor regions 5 (the region along the line c-d). Then, a high level of light-receiving property can be obtained in this region with long wavelength light that is primarily absorbed deep inside compared to short wavelength light.

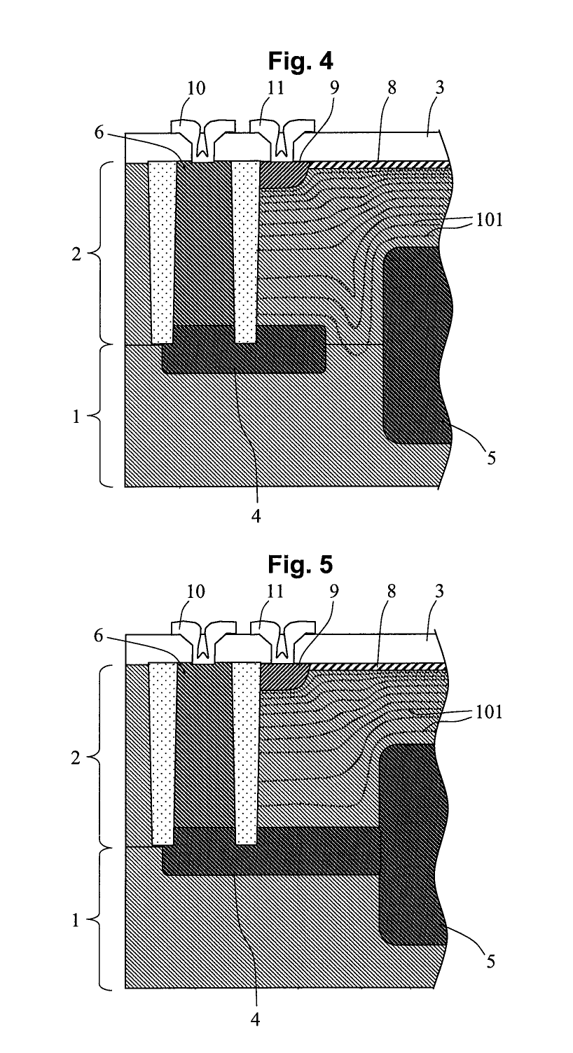

Behavior of electron-hole pairs generated in the light-receiving element according to this embodiment is described hereafter with reference to FIGS. 4 and 5. FIG. 4 shows a structure of the light-receiving element shown in FIGS. 1A and 1B. FIG. 5 shows a structure of a light receiving element modified from FIGS. 1A and 1B in a layout of the P+ type semiconductor region 4. The figures show equipotential lines 101 near the P+ type semiconductor region 4 and P+ type semiconductor region 5 in the light-receiving element according to this embodiment. Some regions shown in FIGS. 1A and 1B are omitted because they are irrelevant to explanation.

Holes of electron-hole pairs reach the P+ type semiconductor region 6 serving as the anode contact layer from the P+ type semiconductor region 5 via the P+ type semiconductor region 4. When the P− type semiconductor substrate 1 and P− type semiconductor layer 2 having low impurity concentrations are present between the P+ type semiconductor region 5 and P+ type semiconductor region 4 as shown in FIG. 4, a potential barrier against holes is formed. Therefore, resistance components are increased in a region where the P+ type semiconductor region 5 and P+ type semiconductor region 4 faces each other and frequency performance are deteriorated as seen from the aforementioned expression of the frequency performance fc.

For this reason, as shown in the planar layout of FIG. 1B, and in FIG. 5, the selectively formed P+ type semiconductor region 5 partly makes contact with the P+ type semiconductor region 4 having an impurity concentration higher than that of the P− type semiconductor layer 2 at more than one place. By this arrangement, the resistance to the transfer of holes of electron-hole pairs generated by incident light to the P+ type semiconductor region 6 is reduced and frequency performance are improved.

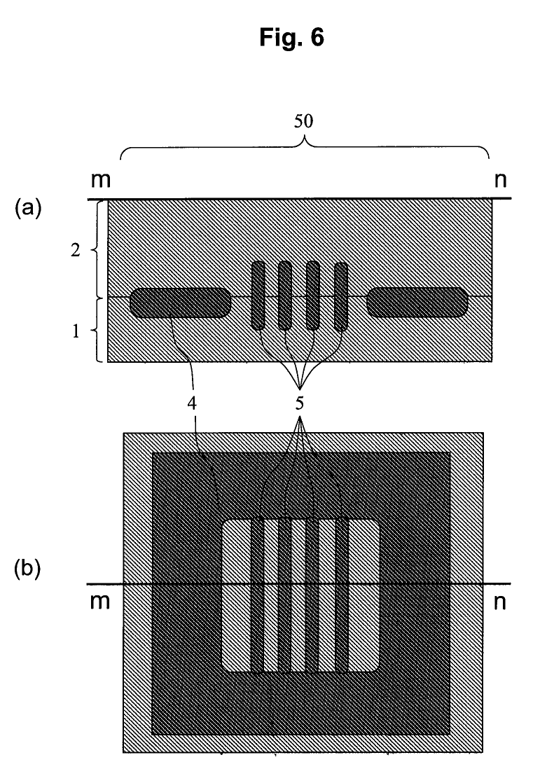

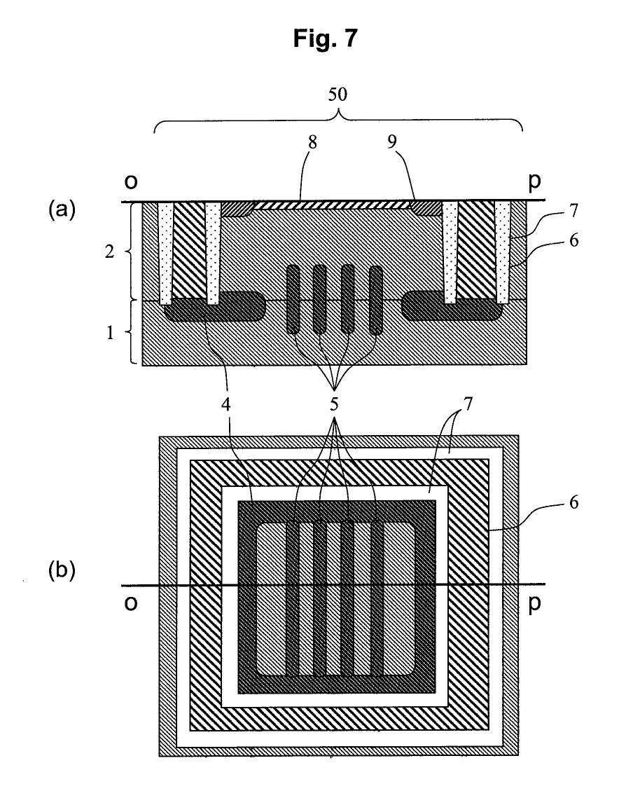

The light-receiving element portion 50 in this embodiment can be produced by known production techniques. FIGS. 6A and 7A are cross-sectional views of an essential portion in manufacturing processes. FIGS. 6B and 7B are plane views corresponding to the cross-sectional views, respectively. FIGS. 6A and 7A are cross-sectional views along lines m-n and o-p in FIGS. 6B and 7B, respectively. FIGS. 6B and 7B show plane views near an interface between the P− type semiconductor substrate 1 and P− type semiconductor layer 2. The N+ type semiconductor region 8 and N+ type semiconductor region 9 formed near the surface are not shown in FIG. 7B.

As shown in FIGS. 6A and 6B, P type impurity ions are implanted in the P− type semiconductor substrate 1 to form the P+ type semiconductor regions 4 and 5. The selectively formed P+ type semiconductor region 5 can easily be formed using a mask pattern during ion implantation. Then, the P− type semiconductor layer 2 is epitaxially grown on the P− type semiconductor substrate 1 to a thickness of approximately 2 μm by CVD (Chemical Vapor Deposition).

As shown in FIGS. 7A and 7B, the P+ type semiconductor region 6 is formed by high energy ion implantation and subsequent thermal diffusion so that it is connected to the P+ type semiconductor region 4 at the bottom. Then, the N+ type semiconductor region 8 and N+ type semiconductor region 9 are sequentially formed by ion implantation and diffusion.

Then, the element separation insulating layer 7 consisting of silicon oxide (SiO₂) is formed by a known STI (shallow trench isolation) technique (trench type separator formation technique). The protective insulating film 3 is formed on a part of the P− type semiconductor layer 2 as shown in FIGS. 1A and 1B. Then, the protective insulating film 3 above the anode and cathode contact layers is etched to open and the electrodes 10 and 11 are formed. In the above process, the light-receiving element portion 50 of this embodiment can be produced.

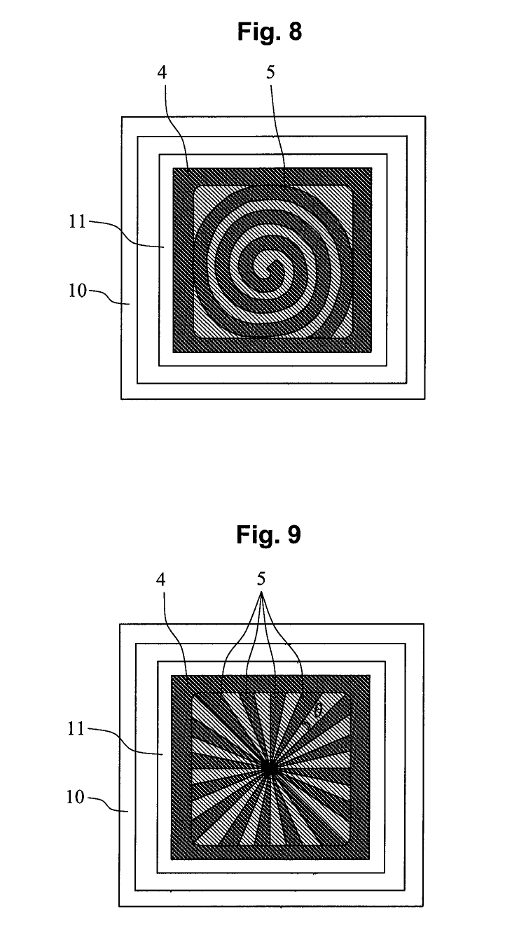

Here, the selectively formed P+ type semiconductor region 5 can be modified in the planar layout to improve operation properties (light-receiving sensitivity and high speed response). FIGS. 8 and 9 are illustrations showing modified embodiments of the planar layout of the P+ type semiconductor region 5. In FIG. 8, the P+ type semiconductor region 5 has a spiral pattern starting from any central point within the light-receiving element portion 50. In FIG. 9, the P+ type semiconductor region 5 has a radial pattern within the light-receiving element portion 50. Particularly in the latter case, the P+ type semiconductor region 5 has a radial pattern extending from any central point within the light-receiving element portion 50 and a plurality of the P+ type semiconductor regions 5 is arranged so that PN junction ends of adjacent P+ type semiconductor regions 5 are so formed as to make an equal angle θ with the P− type semiconductor layer 2 in-between. The light-receiving element portion 50 is irradiated with incident light having a nearly circular or oval cross-section regardless of applications. Particularly, when the light-receiving element portion 50 is irradiated with incident light in a positionally stable manner, the following benefit is obtained; that is to say, by irradiating the light-receiving element portion 50 with incident light at a specific point on the planar layout, stabilized properties can be obtained even if an optical diameter of incident light is changed.

For example, provided that the light-receiving element portion 50 is irradiated with incident light at a specific point on the planar layout in a stable manner, a center of symmetry of irradiation light such as a laser beam is placed on a center of the radial pattern of the P+ type semiconductor region 5 within the light-receiving element portion 50. In this way, even if the incident light beam is changed in optical diameter without any change in shape, a ratio of an irradiation area of the P+ type semiconductor region 5 to a total irradiation area of the incident light is always constant. The light-receiving sensitivity of a light-receiving element varies depending on the number of photons of incident light. The number of photons contained in incident light varies depending on the power of incident light. A light-receiving element receives a same number of photons for the same power even if the optical diameter of incident light is changed.

Therefore, when the ratio of the irradiation area of the P+ type semiconductor region 5 to the total irradiation area of incident light is always constant, the light-receiving sensitivity is always constant even if the optical diameter of incident light is changed provided that the power of incident light is constant. On the other hand, when the ratio is changed as the optical diameter of incident light is changed, the ratio of an area of the P− type semiconductor layer 2 above the P+ type semiconductor region 5 where avalanche amplification primarily occurs to an area of the P− type semiconductor layer 2 above the region interposed between the P+ type semiconductor regions 5 is altered. Then, the fraction of number of photons contributing to avalanche amplification is changed, whereby the light-receiving sensitivity becomes unstable. For this reason, the planar layout of the P+ type semiconductor region 5 can be modified as shown in FIGS. 8 and 9 so that constant light-receiving sensitivity can be obtained with no influence from any change in the optical diameter of incident light. Then, a highly accurate light-receiving element having high speed response and high light-receiving sensitivity can be formed.

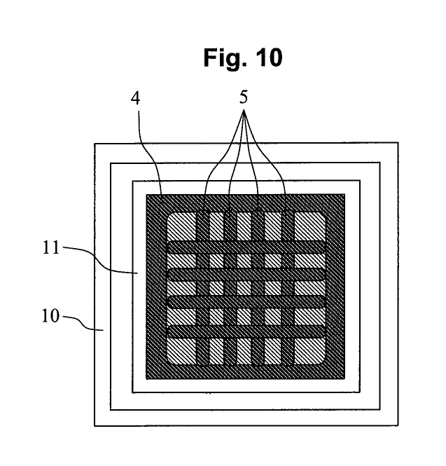

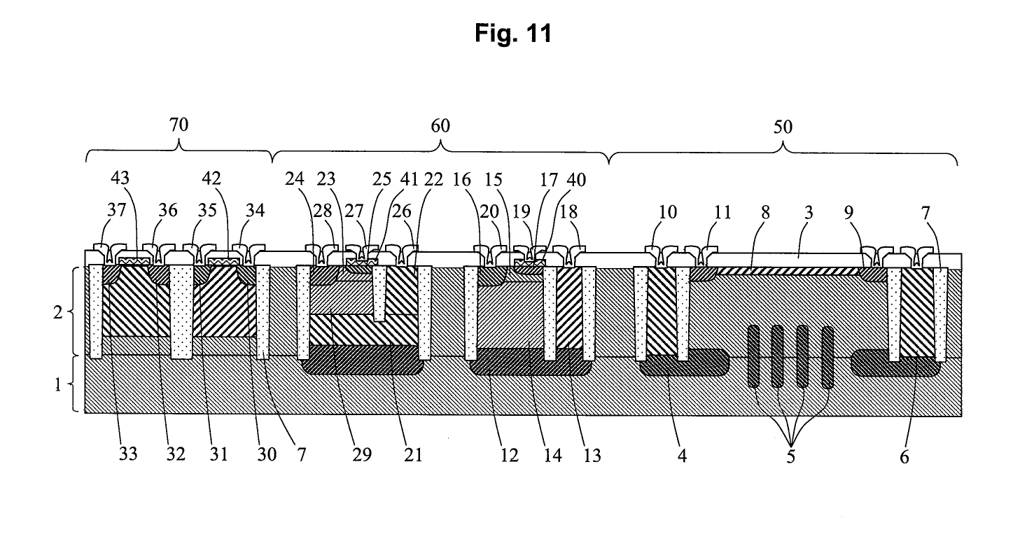

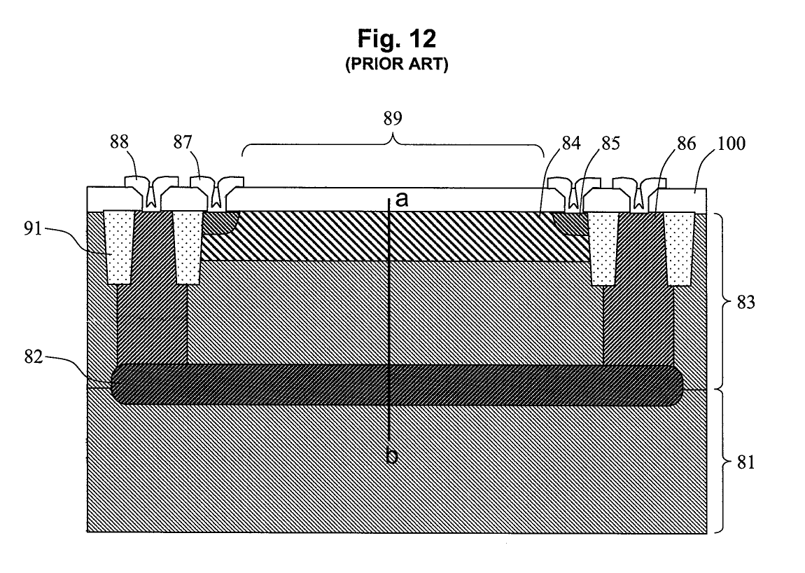

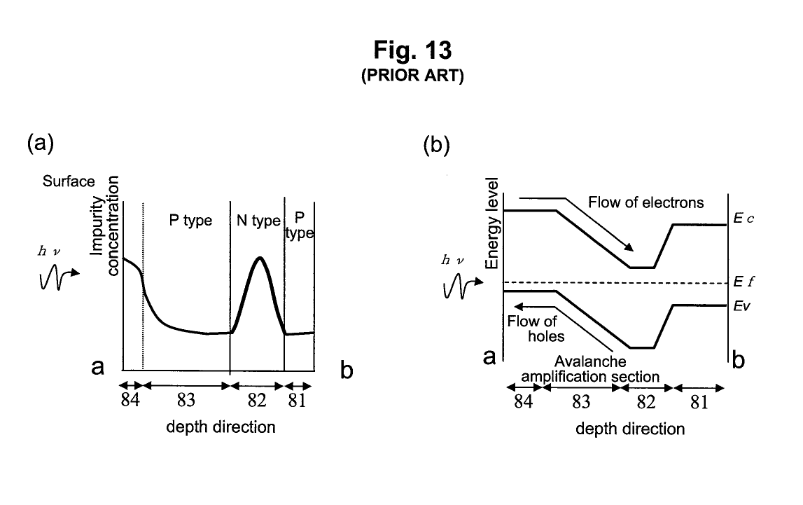

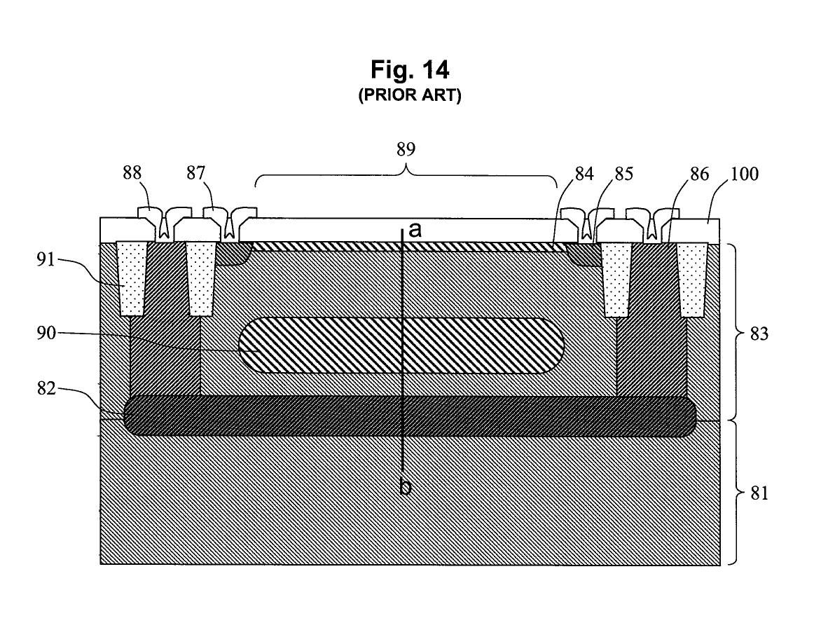

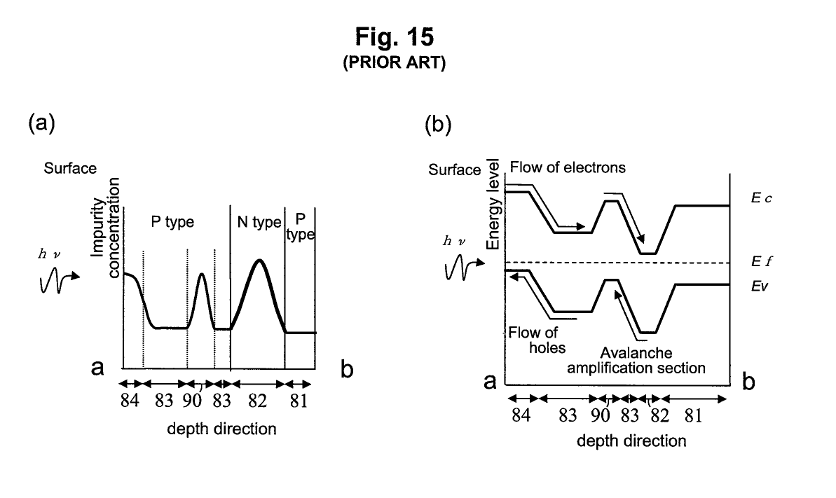

The planar layout of the P+ type semiconductor region 5 is not confined to the aforementioned patterns. In addition to the slit, spiral, and radial patterns given by way of example, their combination can be used. Furthermore, no problem will occur with any pattern anticipated based on them such as a pattern symmetric about a specific point on the light-receiving element portion 50 and a pattern of n-order of rotational symmetry. For example, as shown in FIG. 10, a lattice pattern consisting of a combination of horizontal and vertical slits arranged in parallel at equal intervals can be used. In such a case, compared to a slit pattern in one direction, the P− type semiconductor layer 2 positioned above the P+ type semiconductor region 5 that contributes to avalanche amplification is increased in area. Then, the current amplification leads to improved light-receiving sensitivity even if incident light has a relatively low optical signal power.

The light-receiving element portion 50 of this embodiment can operate with conductivity types of impurities being reversed. Furthermore, silicon is the most preferable material for the P− type semiconductor substrate 1. However, this is not restrictive and other semiconductors such as silicon germanium (SiGe) and compound semiconductors can be used.

### Second Embodiment

FIG. 11 is a cross-sectional view of an optical semiconductor device (OEIC device) in the second embodiment relating to the present invention. The light-receiving element portion 50 of the optical semiconductor device according to the present invention is formed by selective ion implantation using a mask pattern through known production techniques as described above. Therefore, it can easily be integrated on the same substrate with bipolar transistors and MOS (metal oxide semiconductor) transistors, and these are formed in common process.

In FIG. 11, a first transistor portion 60 where an NPN bipolar transistor and a vertical PNP transistor are provided and a second transistor portion 70 where a CMOS transistor is provided are formed on a P− type semiconductor substrate 1 in addition to the light-receiving element portion 50. The light-receiving element portion 50, first transistor portion 60, and second transistor portion 70 are separated from each other by element separation insulating layers 7 extending to the P− type semiconductor substrate 1 or to an N+ type semiconductor region 12.

The structure of the first and second transistor portions 60 and 70 is described hereafter. The first transistor portion 60 includes an NPN bipolar transistor (the NPN-Tr, hereafter) having an N type collector part, a P type base part, and an N type emitter part and a vertical PNP bipolar transistor (the vertical PNP-Tr, hereafter) having a P type collector part, an N type base part, and a P type emitter part. The N type collector part of the NPN-Tr is constituted by an N type collector region 14 formed by diffusing an N type impurity in the P− type semiconductor layer 2, the N+ type semiconductor region 12 and an N type semiconductor region 13 as a collector contact, and a collector electrode 18 formed on the N type semiconductor region 13. The P type base part is constituted by an active base layer 15 consisting of a P type semiconductor region, a base contact region 16 consisting of a P+ type semiconductor region, and a base electrode 20 formed on the base contact region 16. The N type emitter part is constituted by an emitter region 17 formed on the active base layer 15 and containing an N type impurity, a polycrystalline semiconductor layer 40 formed on the emitter region 17 and having a high concentration of N type impurities, and an N type emitter electrode 19 formed on the polycrystalline semiconductor layer 40.

The P type collector part of the vertical PNP-Tr is constituted by a P+ type semiconductor region 21 serving as a collector contact, a P type semiconductor region 22 formed on the P+ type semiconductor region 21 and surrounded by the element separation insulating layer 7, and a P type collector electrode 26 formed on the P type semiconductor region 22. The N type base part is constituted by an N type active base region 23 formed on an N type semiconductor region 29, an N type contact base region 24 formed on the N type semiconductor region 29 in contact with the N type active base region 23, and a base electrode 28. The P type emitter part is constituted by a P type emitter region 25 formed on the N type active base region 23, a polycrystalline semiconductor layer 41 formed on the P type emitter region 25, and an emitter electrode 27 formed on the polycrystalline semiconductor layer 41.

The light-receiving element portion 50 of the present invention improves the light-receiving property by means of avalanche amplification without any increase in the thickness of the P− type semiconductor layer 2 that affects transistor properties. Then, the thickness of the P− type semiconductor layer 2 that is optimized for the bipolar transistor properties does not need to be changed for satisfying the light-receiving properties. The bipolar transistor can be designed with no restriction from the light-receiving element structure.

The second transistor portion 70 includes N channel type and P channel type MOS transistors. These MOS transistors are separated by an element separation insulating layer 7. Diffusion layers of the MOS transistors are formed in an upper portion of the P− type semiconductor layer 2. An N type source region 33, N type drain region 32, and N type polycrystalline semiconductor layer 43 serving as a gate electrode constitute an N channel type MOS transistor. A P type source region 31, P type drain region 30, and P type polycrystalline semiconductor layer 42 serving as a gate electrode constitute a P channel type MOS transistor. Reference numbers 34 to 37 refer to electrodes formed on source and drain regions of the N channel and P channel MOS transistors.

The light-receiving element portion 50 of the present invention allows MOS transistors to be formed on the same substrate. With such a structure, parasitic capacitance of wire bonding and external disturbance noise can be reduced. Then, the optical semiconductor device sufficiently utilizing the capability of the light-receiving element having high speed response and high light-receiving sensitivity can be realized.

As described above, the present invention realizes high light-receiving sensitivity by means of current amplification and high speed response as a result of reduced parasitic capacitance and parasitic resistance. Having high light-receiving properties for light of a wide range of wavelengths, the present invention is useful in optical detectors for optical discs using multiple kinds of light.

What is claimed is:

1. An optical semiconductor device including a light-receiving element converting an incident light signal to a current signal and amplifying the current signal, the light-receiving element comprising:
a semiconductor layer of a first conductivity type formed on a semiconductor substrate of the first conductivity type and having an impurity concentration equal to or lower than that the semiconductor substrate;
a first semiconductor region of the first conductivity type formed by delimiting a specific region of the semiconductor layer with an element separation region;
a second semiconductor region of a second conductivity type formed on the first semiconductor region and having an impurity concentration higher than that the first semiconductor region;
a third semiconductor region of the first conductivity type formed in a region of the semiconductor layer which is separated from the first and the second semiconductor regions by the element separation region and having an impurity concentration higher than that the first semiconductor region;
a fourth semiconductor region of the first conductivity type formed between the semiconductor substrate and the third semiconductor region and having an impurity concentration higher than that the semiconductor substrate; and
a fifth semiconductor region of the first conductivity type formed across the semiconductor substrate and the first semiconductor region, an upper portion of the fifth semiconductor region penetrating into a specific depth of the first semiconductor region and having an impurity concentration higher than that the semiconductor substrate, and wherein
amplification of the current signal occurs when a reverse voltage is applied between the second semiconductor region and a surface portion of the third semiconductor region.

2. An optical semiconductor device according to claim 1, wherein a top of the upper portion of the fifth semiconductor region in the first semiconductor region is located a depth such that avalanche amplification of the current signal occurs in the first semiconductor region positioned above the fifth semiconductor region when the reverse voltage is applied.

3. An optical semiconductor device according to claim 1, wherein the fifth semiconductor region is provided in multiple separate regions in the first semiconductor region.

4. An optical semiconductor device according to claim 2, wherein the fifth semiconductor region is provided in multiple separate regions in the first semiconductor region.

5. An optical semiconductor device according to claim 1, wherein the fourth semiconductor region is extended to within the first semiconductor region and connected to the fifth semiconductor region.

6. An optical semiconductor device according to claim 2, wherein the fourth semiconductor region is extended to within the first semiconductor region and connected to the fifth semiconductor region.

7. An optical semiconductor device according to claim 3, wherein the fourth semiconductor region is extended to within the first semiconductor region and connected to the fifth semiconductor region.

8. An optical semiconductor device according to claim 4, wherein the fourth semiconductor region is extended to within the first semiconductor region and connected to the fifth semiconductor region.

9. An optical semiconductor device according to claim 1, wherein the fifth semiconductor region has a spiral pattern or a pattern including a spiral pattern in a planar layout.

10. An optical semiconductor device according to claim 2, wherein the fifth semiconductor region has a spiral pattern or a pattern including a spiral pattern in a planar layout.

11. An optical semiconductor device according to claim 1, wherein the fifth semiconductor region has a radial pattern or a pattern including a radial pattern in a planar layout.

12. An optical semiconductor device according to claim 2, wherein the fifth semiconductor region has a radial pattern or a pattern including a radial pattern in a planar layout.

13. An optical semiconductor device according to claim 1, wherein the fifth semiconductor region has a pattern in a planar layout in which an area ratio of the fifth semiconductor region to an irradiation area of incident light is always constant in the irradiation area.

14. An optical semiconductor device according to claim 2, wherein the fifth semiconductor region has a pattern in a planar layout in which an area ratio of the fifth semiconductor region to an irradiation area of incident light is always constant in the irradiation area.

15. An optical semiconductor device according to claim 3, wherein the fifth semiconductor region has a pattern in a planar layout in which an area ratio of the fifth semiconductor region to an irradiation area of incident light is always constant in the irradiation area.

16. An optical semiconductor device according to claim 4, wherein the fifth semiconductor region has a pattern in a planar layout in which an area ratio of the fifth semiconductor region to an irradiation area of incident light is always constant in the irradiation area.
